(19) United States
(12) Patent Application Publication
(10) Pub. No.: US 2012/0084028 A1
(43) Pub. Date: Apr. 5, 2012

(54) Framework and Methodology for a Real-Time Fine-Grained Power Profiling with Integrated Modeling

(75) Inventors: Prathiba Kumar, Tamilnadu (IN); Satish Kumar Sadasivam, Tamilnadu (IN); Giri M. Prabhakar, Bangalore (IN)

(73) Assignee: IBM CORPORATION, Armonk, NY (US)

(21) Appl. No.: 12/895,074

(22) Filed: Sep. 30, 2010

(51) Int. Cl. G06F 19/00; G01R 21/00

(52) U.S. Cl. 702/61

(57) ABSTRACT

A method, a system and a computer program product for determining power consumption levels for granular segments of program code in a data processing system. A power profiling utility (PPU) utilizes/comprises a power monitoring module, a power profiler module, a performance profiler and a power modeling component which enables PPU to efficiently characterize power consumption of various types of applications. The PPU uses a power measurement device to obtain power consumption measurements corresponding to execution of a first code segment. Additionally, the PPU identifies information about program characteristics of granular code segments within the first code segment. The PPU then determines total power consumption for execution of the first code segment from an aggregation of power consumption measurements corresponding to all iterations of the first code segment. Ultimately, the PPU derives from the total power consumption calculated for the first code segment a finer grained power profile by using the program characteristics information and power modeling information.

### BACKGROUND

1. Technical Field

The present invention generally relates to power measurement systems and in particular to power measurement systems for data applications.

2. Description of the Related Art

Measurement of various performance metrics has been the focus of performance monitoring tools in the industry. With the ever-increasing focus on energy-efficient computing, there arises a need to understand the power consumption of individual applications/programs at various fronts. In data-center level energy management, there exists a need to isolate the high-energy applications to enable efficient distribution of workloads. In addition, the programmer would need to understand the power consumption of his application—to enable tuning for energy by applicable programming techniques, performance tunings trade-off for energy, etc (i.e., to strategically implement coding techniques that enhance energy/power performance). The application energy behavior will further help style processor design for power-aware computing. Power-consumption studies have been gaining momentum and power-performance trade-offs, which were unheard of in the past, is common practice today. While tools and techniques to measure System power (via out-of-band measurement) are prevalent, in-band measurement to capture the power consumption of individual applications has not been effectively addressed.

Current power measurement tools provide only details of system power. These system power measurement tools differ in two ways, (a) the measurement devices used and (b) the platform at which the measurement is controlled and data presented. The tools exploit either an in-built device or external pluggable devices and present the system power consumption to the user on an operating system (OS) front or at an external system management console. A potential application power measurement system based on current power measurement tools may be based on limiting the running of applications to the single application for which power data is required and then measuring the system power. However, in this setup, system power cannot be totally attributed to the application's power consumption because the Operating System is consuming power as well. In addition, this setup is costly and feasible only in an experimental setup. Real-time workload monitoring in systems in production is not feasible.

Power modeling has largely been the approach to estimate power/energy consumption of applications. One approach towards power modeling is to predict power consumption by monitoring the performance monitoring counters and estimating the power consumption based on “weightage” given to the events counted. This approach has inherent drawbacks, such as (a) only limited events can be measured at any given time and (b) the energy behavior depends on too many events to be effectively estimated by monitoring only a handful of events.

### BRIEF SUMMARY

Disclosed are a method, a system and a computer program product for determining power consumption levels for granular segments of program code in a data processing system. A power profiling utility (PPU) utilizes/comprises a power monitoring module, a power profiler module, a performance profiler and a power modeling component which enables PPU to efficiently characterize power consumption of various types of applications. The PPU uses a power measurement device to obtain power consumption measurements corresponding to execution of a first code segment. Additionally, the PPU identifies information about program characteristics of granular code segments within the first code segment. The PPU then determines total power consumption for execution of the first code segment from an aggregation of power consumption measurements corresponding to all iterations of the first code segment. Ultimately, the PPU derives from the total power consumption calculated for the first code segment a finer grained power profile by using the program characteristics information and power modeling information.

The above summary contains simplifications, generalizations and omissions of detail and is not intended as a comprehensive description of the claimed subject matter but, rather, is intended to provide a brief overview of some of the functionality associated therewith. Other systems, methods, functionality, features and advantages of the claimed subject matter will be or will become apparent to one with skill in the art upon examination of the following figures and detailed written description.

The above as well as additional objectives, features, and advantages of the present invention will become apparent in the following detailed written description.

### BRIEF DESCRIPTION OF THE DRAWINGS

The description of the illustrative embodiments is to be read in conjunction with the accompanying drawings, wherein:

FIG. 1 provides a block diagram representation of an example data processing system within which the invention is practiced, according to one embodiment;

FIG. 2 illustrates a power profiler framework/system, according to one embodiment;

FIG. 3 illustrates the parallel, serial and sequential execution of functions in a power profiling framework, according to one embodiment;

FIG. 4 illustrates an example outline of code sections, a record of the corresponding power consumption levels and an example power consumption plot, according to one embodiment; and

FIG. 5 is a flow chart illustrating the processes within the method for obtaining a total power consumption (over all iterations) for a particular first segment of code and deriving from said total power consumption a power consumption level corresponding to a more granular segment of code from within the first segment of code, according to one embodiment.

### DETAILED DESCRIPTION

The illustrative embodiments provide a method, a system and a computer program product for determining power consumption levels for granular segments of program code in a data processing system. A power profiling utility (PPU) utilizes/comprises a power monitoring module, a power profiler module, a performance profiler and a power modeling component which enables PPU to efficiently characterize power consumption of various types of applications. The PPU uses a power measurement device to obtain power consumption measurements corresponding to execution of a first code segment. Additionally, the PPU identifies information about program characteristics of granular code segments within the first code segment. The PPU then determines total power consumption for execution of the first code segment from an aggregation of power consumption measurements corresponding to all iterations of the first code segment. Ultimately, the PPU derives from the total power consumption calculated for the first code segment a finer grained power profile by using the program characteristics information and power modeling information.

In the following detailed description of exemplary embodiments of the invention, specific exemplary embodiments in which the invention may be practiced are described in sufficient detail to enable those skilled in the art to practice the invention, and it is to be understood that other embodiments may be utilized and that logical, architectural, programmatic, mechanical, electrical and other changes may be made without departing from the spirit or scope of the present invention. The following detailed description is, therefore, not to be taken in a limiting sense, and the scope of the present invention is defined by the appended claims and equivalents thereof.

It is understood that the use of specific component, device and/or parameter names (such as those of the executing utility/logic described herein) are for example only and not meant to imply any limitations on the invention. The invention may thus be implemented with different nomenclature/terminology utilized to describe the components/devices/parameters herein, without limitation. Each term utilized herein is to be given its broadest interpretation given the context in which that terms is utilized.

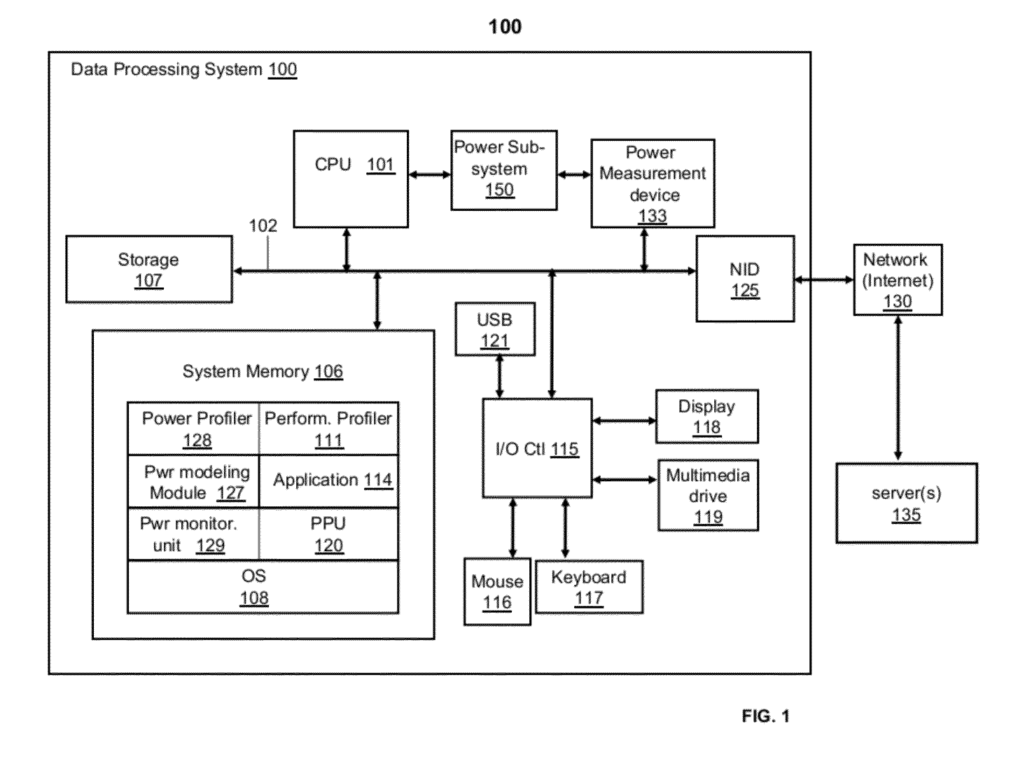

With reference now to the figures, and beginning with FIG. 1, there is depicted a block diagram representation of an example data processing system (DPS), as utilized within one embodiment. DPS may be a server, a personal computer, a portable device, such as a personal digital assistant (PDA), a smart phone, and/or other types of electronic devices that may generally be considered processing devices. As illustrated, DPS 100 comprises at least one processor or central processing unit (CPU) 101 connected to system memory 106 via system interconnect/bus 102. Also connected to system bus 102 is input/output (I/O) controller 115, which provides connectivity and control for input devices, of which pointing device (or mouse) 116 and keyboard 117 are illustrated. I/O controller 115 also provides connectivity and control for output devices, of which display 118 is illustrated. Additionally, a multimedia drive 119 (e.g., compact disk read/write (CDRW) or digital video disk (DVD) drive) and USB (universal serial bus) port 121 are illustrated, coupled to I/O controller 115. Multimedia drive 119 and USB port 121 enable insertion of a removable storage device (e.g., optical disk or “thumb” drive) on which data/instructions/code may be stored and/or from which data/instructions/code may be retrieved. DPS 100 also comprises storage 107, within/from which data/instructions/code may also be stored/retrieved. According to one embodiment, DPS 100 comprises power sub-system 150 that provides power to one or more of the various hardware devices of DPS 100. Power sub-system 150 includes a battery power supply and/or a connection for an external power supply. Power sub-system 150 is connected to more or more hardware devices of DPS 100 (e.g. CPU 101 and system memory 106) and these hardware devices consume variable amounts of power during execution of one or more segments of program code or applications. Additionally, as provided by the illustrated embodiment, DPS 100 comprises power measurement device 133. In one embodiment, power measurement device 133 measures power consumption from power sub-system 150 of one or more devices during execution of program code segments.

To further enable external network connection, DPS 100 also includes network interface component (NIC) 125, by which DPS 100 may connect to one or more access/external networks 130, of which the Internet is provided as one example. In this implementation, the Internet represents/is a worldwide collection of networks and gateways that utilize the Transmission Control Protocol/Internet Protocol (TCP/IP) suite of protocols to communicate with one another. NIC 125 may be configured to operate via wired or wireless connection to an access point of the network. Network 130 may be an external network such as the Internet or wide area network (WAN), or an internal network such as an Ethernet (local area network—LAN) or a Virtual Private Network (VPN). Connection to the external network 130 may be established with one or more servers 135, which may also provide data/instructions/code for execution on DPS 100, in one embodiment.

In addition to the above described hardware components of data processing system 100, various features of the invention are completed/supported via software (or firmware) code or logic stored within memory 106 or other storage and executed by Processor 101. Thus, for example, illustrated within memory 106 are a number of software/firmware/logic components, including operating system (OS) 108 and software application 114. Also provided within memory 106 (and associated with OS 108, in one embodiment) are components of a power profiler framework including power profiler module 128, power modeling module 127, power monitoring unit 129 and performance profiler 111. In addition, memory 106 comprises Power Profiling utility (PPU) 120 (which may be alternatively referred to as Power Profiling logic 120). In actual implementation, PPU 120 may be combined with one or more key components of the power profiler framework to provide a single executable component, collectively providing the various functions of each individual component when the corresponding combined component is activated. For simplicity, PPU 120 is illustrated and described as a stand alone or separate logic/firmware component, which provides specific functions, as described below.

In one embodiment, server 135 represents a software deploying server, and DPS 100 communicates with the software deploying server (135) via network (e.g., Internet 130) using network interface device 125. Then, PPU 120 may be deployed from/on the network, via software deploying server 135. With this configuration, software deploying server can perform all of the functions associated with the execution of PPU 120. Accordingly, DPS 100 is not required to utilize internal computing resources of DPS 100 to execute PPU 120.

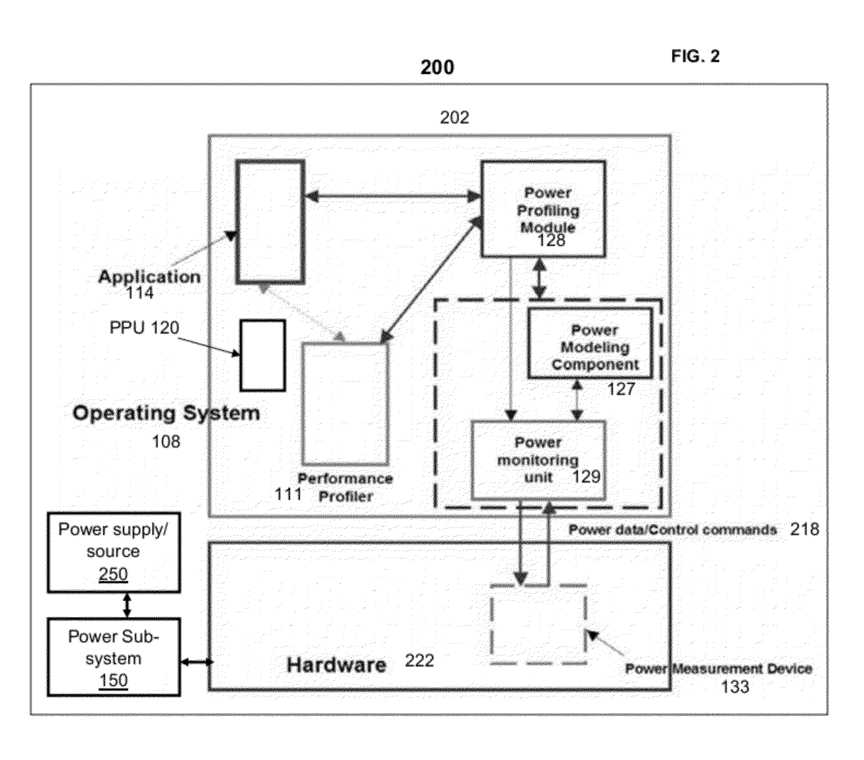

Among the software code/instructions/logic provided by PPU 120, and which are specific to the invention, are: (a) logic for measuring a first level of power consumption associated with execution of program code; (b) logic for mapping said first level of power consumption to a first segment of program code; wherein said first segment of program code represents a first level of code granularity, and said first level of power consumption is measured at a particular iteration of execution of said first segment of program code; (c) logic for aggregating levels of power consumption corresponding to iterations of execution of a first code segment; (d) logic for determining total power consumption associated with said first segment of program code from said levels of power consumption aggregated; (e) logic for obtaining from said total power consumption a distribution of power consumption for the first code segment, based on said program characteristics and a power model; and (f) logic for deriving from said total power consumption a second level of power consumption corresponding to a more granular segment of code from among said first segment of code. According to the illustrative embodiment, when processor 101 executes PPU 120, processor 101 enables DPS 100 to initiate a series of functional processes that enable the above functional features as well as additional features/functionality. These features/functionalities are described in greater detail below within the description of FIGS. 2-5.

Those of ordinary skill in the art will appreciate that the hardware components and basic configuration depicted in FIG. 1 may vary. The illustrative components within DPS 100 are not intended to be exhaustive, but rather are representative to highlight essential components that are utilized to implement the present invention. For example, other devices/components may be used in addition to or in place of the hardware depicted. The depicted example is not meant to imply architectural or other limitations with respect to the presently described embodiments and/or the general invention. The data processing system depicted in FIG. 1 may be, for example, an IBM eServer pSeries system, a product of International Business Machines Corporation in Armonk, N.Y., running the Advanced Interactive Executive (AIX) operating system or LINUX operating system.

FIG. 2 illustrates a power profiler framework/system, according to one embodiment. Power profiler system 200 comprises (a) hardware component 222, (b) software components 202 and (c) power data/control command signals 218. Hardware component 222 comprise power measurement device 133. Hardware components 222 receive power from power sub-system 150 which includes or is connected to power supply/source 250. Software components 202 comprise operating system (OS) platform 108. Residing/executing on OS platform 108 are application 114, power profiling/profiler (module) 128, performance profiler 111, power modeling component 127 and power monitoring unit 129.

Power Profiler 128 is invoked in conjunction with the program invocation and performance profiler initialization. Power Profiler 128 initializes power measurement via the hardware facilities. The power measurement is recorded at a given granularity and the data is fed into power-modeling component 127 that maps the power consumption to the lowest granularity possible using the program characteristics information obtained from performance profiler 111. Power profiler 128 tracks the scheduling of the application process and controls the power measurement devices accordingly. Power Profiler 128 integrates the power data with the performance profile and presents an overview of the power consumption of application 114.

Power Measurement device 133 normally consist of a resistor on power supply 250 to the processor or core or some mechanism that monitors (via power monitoring unit 129) the power drawn from the power supply 250 at all times. Power Measurement device 133 may be configured to function in a number of ways including the following: (a) Polling at regular intervals; (b) Initialization and reading of an accumulator register; and (c) Generation and retrieval of a trace stored in an internal buffer. Power measurement device 133 is initialized and the power data recorded during program execution as directed by Power Profiler (module) 128.

Power Modeling component 127 is used to dissect the power consumed to the lowest possible granularity. Power Modeling component 127 interfaces with power monitoring unit 129 as well as the application/program characteristics data to breakdown the power data into power consumption at the instruction level. The power data thus broken down by power modeling component 127 is then stored and integrated with the performance metrics being derived by performance-profiling module 111.

Power Profiler 128 is in charge of directing the measurement of the power data in conjunction with application execution. Power Profiler 128 facilitates an interlock between performance profiler 111 and the Power data-Power Model unit (within power modeler 127) to integrate the power data alongside the performance data.

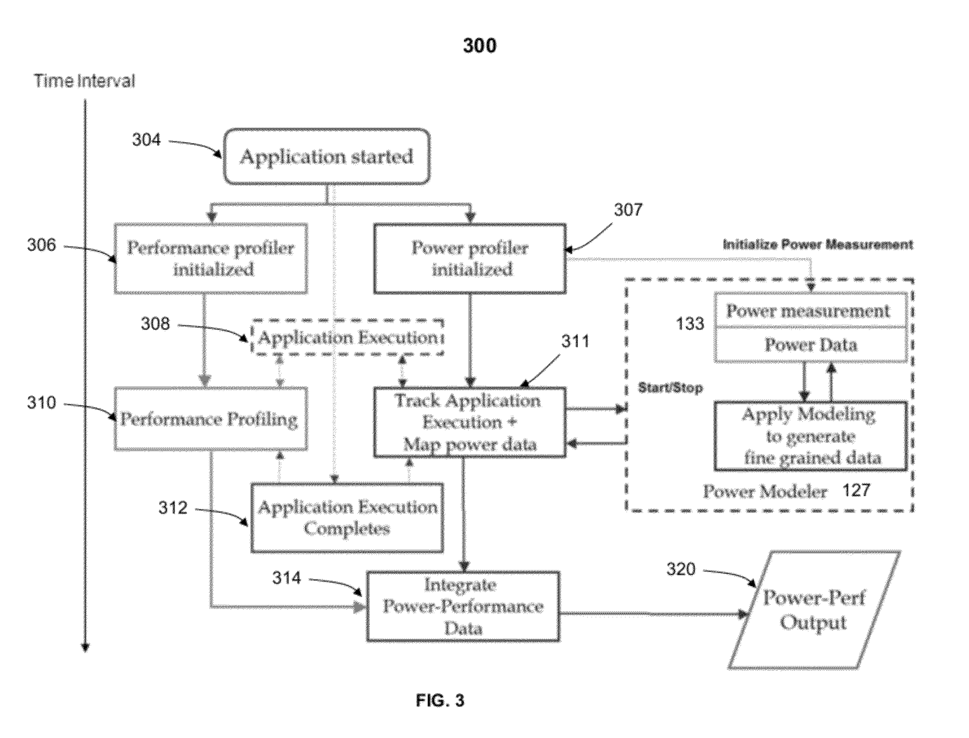

FIG. 3 illustrates the parallel, serial and sequential execution of functions in a power profiling framework, according to one embodiment. According to operations 300, at an initial time interval (i.e., at process block 304), PPU 120 detects the initiation of application 114. In response to detecting the start of application 114, PPU 120 triggers the initialization of both performance profiler 111 and power profiler 128 (as shown at process block 306 and process block 307, respectively). Power Profiler 128 then initializes power measurement by the hardware facilities (e.g., power measurement device 133). As application 114 executes (as shown at process block 308), performance profiler 111 develops (at process block 310) a performance profile for the executing application via a status of application performance data (e.g., program characteristics), wherein said application performance data includes one or more of: (a) characteristics of input data; (b) data availability in a cache; (c) branch penalties; and (d) other factors associated with code execution. At process block 311, power profiler 128 directs the measurement of power data in conjunction with monitoring/tracking the execution of application 114. The power measurement is recorded at a given granularity and the data is fed into power-modeling component 127 along with the program characteristics recorded by performance profiler 111. Power-modeling component 127 maps the power consumption to the lowest granularity possible. Once execution of application 114 is completed, power profiler 128 integrates the power data with the performance profile (as shown at process block 314) and presents an overview of the power consumption of application 114 (as shown at process block 320).

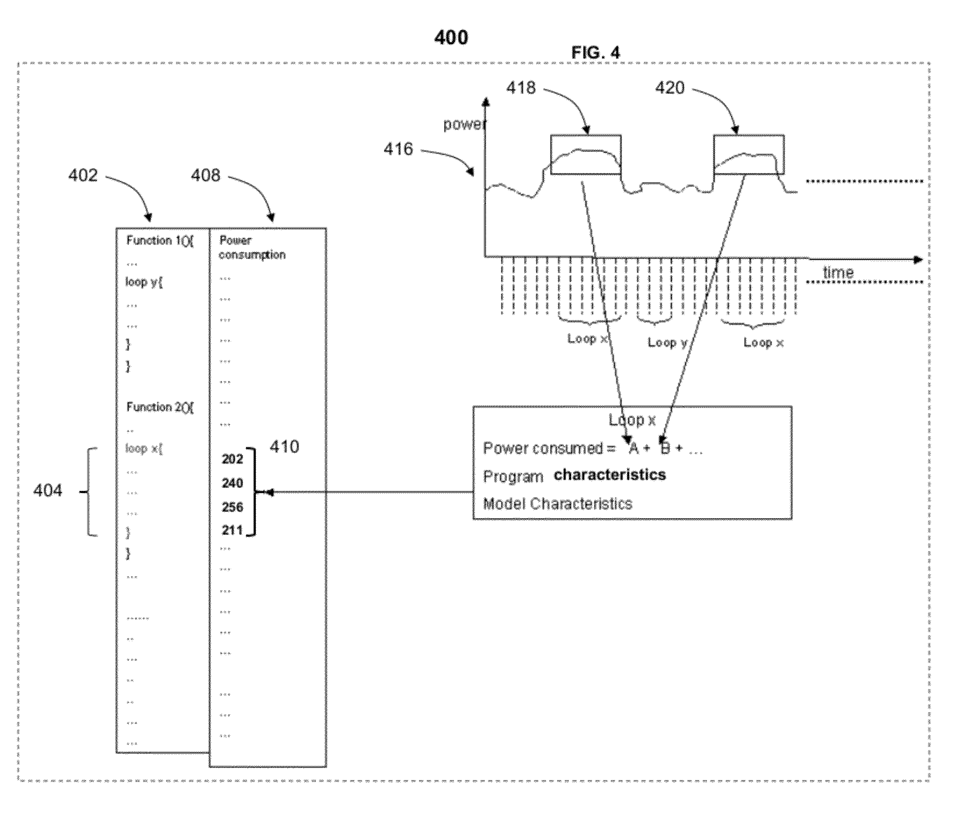

FIG. 4 illustrates an example outline of code sections, a record of the corresponding power consumption levels and an example power consumption plot, according to one embodiment. Profile mapping 400 comprises code block 402, power profile 408 and power consumption plot 416. Illustrated within code block 402 is code segment 404 (i.e., “loop x” 404). As application 114 executes, PPU 120 detects two separate iterations of the loop x 404. Accordingly, power consumption levels for the two separate iterations of execution of loop x are measured as “A” and “B”. The power consumption of loop x 404 is aggregated (i.e., A+B). By applying the power model characteristics and program characteristics, the aggregated/total power (for execution of loop x over two iterations) is split up over granular sections of the code and listed in the power profile 408. As a result, power profile 408 depicts power consumption levels of “202”, “240”, “256” and “211” units of power (collectively illustrated as power consumption levels 410) for the corresponding granular sections of loop x 404.

PPU 120 maps the power consumption data to the sections of the code to come out with a cumulative consumption of power during the entire course of program execution by a given section of the code. Consequently, PPU 120 is able to identify the power hotspots in the code. The profiler records the power consumption over periodic intervals of time (variable) and maps the power consumed to code sections (blocks, modules, functions, etc). The program characteristics of the code sections are also gathered and mapped simultaneously. The power consumed during each iteration of the execution of a code section is aggregated into total power consumption. PPU 120 divides the total power consumption over the more granular sections of the code (basic blocks, instructions, etc) (i.e., subset code of the code section/segment) by using the program characteristics and the power model (information). The variation in power consumption during various phases of execution of the same piece of code can be attributed to various factors such as input data (nature of data), data availability in cache, branch penalties, etc. Power consumption (“A”) for a code execution in the first iteration is plotted within first plot segment 418. Similarly, power consumption (“B”) for the same code execution in the second iteration is plotted within second plot segment 420. Furthermore, PPU 120 provides distribution of power consumption over the first code segment (e.g., loop x 404) which distribution includes finer grained power consumption levels (e.g., collectively illustrated by power consumption levels 410) attributed to granular segments of code (i.e., subsets of the first code segment).

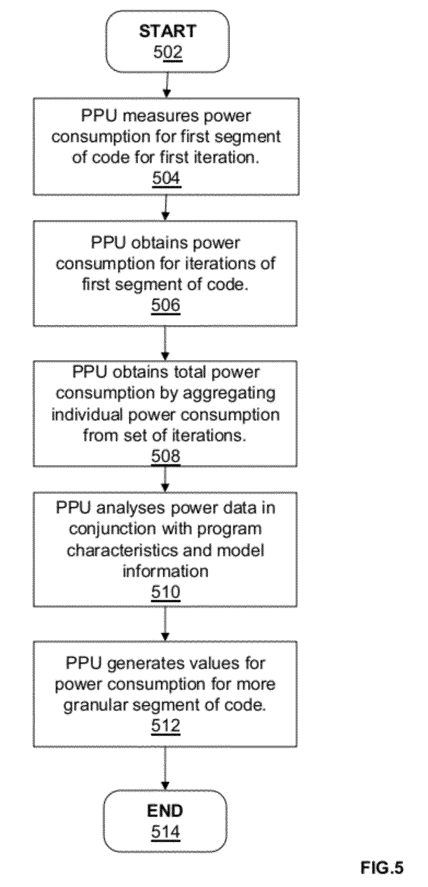

FIG. 5 is a flow chart illustrating the process of obtaining a total power consumption (over all iterations) for a particular first segment of code and deriving from said total power consumption power consumption levels corresponding to more granular segments of code from within the first segment of code, according to one embodiment. The process of FIG. 5 begins at initiator block 502 and proceeds to block 504, at which PPU 120 measures power consumption for execution of a first segment of code during a first iteration. At block 506, PPU 120 obtains power consumption for separate iterations of the execution of a first segment of code. PPU 120 obtains total power consumption by aggregating power consumption for the separate iterations, as shown at block 508. At block 510, PPU 120 analyses power data in conjunction with program characteristics and power model information. At block 512, PPU 120 generates finer grained levels of power consumption corresponding to granular segments of code within the first segment of code, based on the analysis of power data in conjunction with the program characteristics and power model information. The process ends at block 514.

In each of the flow charts above, one or more of the methods may be embodied in a computer readable medium containing computer readable code such that a series of steps are performed when the computer readable code is executed on a computing device. In some implementations, certain steps of the methods are combined, performed simultaneously or in a different order, or perhaps omitted, without deviating from the spirit and scope of the invention. Thus, while the method steps are described and illustrated in a particular sequence, use of a specific sequence of steps is not meant to imply any limitations on the invention. Changes may be made with regards to the sequence of steps without departing from the spirit or scope of the present invention. Use of a particular sequence is therefore, not to be taken in a limiting sense, and the scope of the present invention is defined only by the appended claims.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, R.F, etc., or any suitable combination of the foregoing. Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described below with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks. The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

As will be further appreciated, the processes in embodiments of the present invention may be implemented using any combination of software, firmware or hardware. As a preparatory step to practicing the invention in software, the programming code (whether software or firmware) will typically be stored in one or more machine readable storage mediums such as fixed (hard) drives, diskettes, optical disks, magnetic tape, semiconductor memories such as ROMs, PROMs, etc., thereby making an article of manufacture in accordance with the invention. The article of manufacture containing the programming code is used by either executing the code directly from the storage device, by copying the code from the storage device into another storage device such as a hard disk, RAM, etc., or by transmitting the code for remote execution using transmission type media such as digital and analog communication links. The methods of the invention may be practiced by combining one or more machine-readable storage devices containing the code according to the present invention with appropriate processing hardware to execute the code contained therein. An apparatus for practicing the invention could be one or more processing devices and storage systems containing or having network access to program(s) coded in accordance with the invention.

Thus, it is important that while an illustrative embodiment of the present invention is described in the context of a fully functional computer (server) system with installed (or executed) software, those skilled in the art will appreciate that the software aspects of an illustrative embodiment of the present invention are capable of being distributed as a program product in a variety of forms, and that an illustrative embodiment of the present invention applies equally regardless of the particular type of media used to actually carry out the distribution.

While the invention has been described with reference to exemplary embodiments, it will be understood by those skilled in the art that various changes may be made and equivalents may be substituted for elements thereof without departing from the scope of the invention. In addition, many modifications may be made to adapt a particular system, device or component thereof to the teachings of the invention without departing from the essential scope thereof. Therefore, it is intended that the invention not be limited to the particular embodiments disclosed for carrying out this invention, but that the invention will include all embodiments falling within the scope of the appended claims. Moreover, the use of the terms first, second, etc. do not denote any order or importance, but rather the terms first, second, etc. are used to distinguish one element from another.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. In a data processing system, a computer-implemented method comprising:
measuring a first level of power consumption corresponding to execution of a first segment of program code;
identifying information about program characteristics of the first segment of program code;
obtaining power model information for the first segment of program code;
determining total power consumption for execution of said first segment of program code by aggregating levels of measured power consumption corresponding to a plurality of iterations of execution of said first segment of program code; and
deriving from said total power consumption a second level of power consumption corresponding to a granular segment of code contained within said first segment of code by using the program characteristics information and the power model information that are mapped to particular code segments.

2. The method of claim 1, further comprising:
measuring the first level of power consumption associated with execution of program code for a particular interval of time; and
mapping said first level of power consumption for said particular interval of time to the first segment of program code.

3. The method of claim 1, further comprising:
providing a distribution of power consumption over the first code segment, which distribution includes finer grained power consumption levels attributed to granular segments of code within the first code segment;
wherein said distribution of power consumption over the first code segment is obtained from the total power consumption for the first code segment;
wherein said distribution of power consumption is obtained by using the program characteristics and power modeling information associated with one or more of: (a) the first code segment; and (b) a subset code of the first code segment;
identifying variations in power consumption during different iterations of execution of a same segment of code; and
linking said variations identified to information about program characteristics of particular segments of code, wherein the program characteristics information includes one or more of: (a) characteristic of input data; (b) data availability in a cache; (c) branch penalties; and (d) other factors associated with code execution.

4. The method of claim 1, further comprising:
identifying program characteristics of one or more of: (a) said first segment of program code; and (b) a subset of said first segment of program code;
obtaining a power model information for one or more of: (a) the first segment of program code; and (b) the subset of said first segment of program code;
identifying finer grained power consumption levels by using the program characteristics and power model information corresponding to granular code segments within the first code segment; and
mapping program characteristics information of the granular code segments to corresponding finer grained power consumption levels, wherein the mapping is performed concurrently with a mapping of the finer grained power consumption levels to the granular segments of the first code segment.

5. The method of claim 1, further comprising:
obtaining, from said total power consumption, a distribution of power consumption for executing granular segments of program code from code contained within said first segment of program code by using said program characteristics and a power model;
wherein said first segment of program code represents a first level of code granularity; and
wherein said first level of power consumption is measured during an iteration of execution of said first segment of program code.

6. The method of claim 1, further comprising:
determining power consumption by measuring, via a power measurement device, a level of power consumption by one or more devices that receive power from a power sub-system during execution of one or more segments of program code;
wherein said level of power consumption measures power required by the one or more devices to execute said one or more segments of program code; and
wherein said one or more devices includes a processor executing the one or more segments of program code, and wherein the processor consumes a specific level of power in response to executing one or more segments of program code.

7. A data processing system comprising:
a processor;
a memory having stored therein a utility, which when executed by the processor performs the functions of:
measuring a first level of power consumption corresponding to execution of a first segment of program code;
identifying information about program characteristics of the first segment of program code;
obtaining power model information for the first segment of program code;
determining total power consumption for execution of said first segment of program code by aggregating levels of measured power consumption corresponding to a plurality of iterations of execution of said first segment of program code; and
deriving from said total power consumption a second level of power consumption corresponding to a granular segment of code contained within said first segment of code by using the program characteristics information and power model information that are mapped to particular code segments.

8. The data processing system of claim 7, further comprising:
a power measurement device that performs the function of measuring the first level of power consumption associated with execution of program code for a particular interval of time; and
wherein the utility further performs the function of mapping said first level of power consumption for said particular interval of time to the first segment of program code.

9. The data processing system of claim 7, wherein the utility further performs the function of:
providing a distribution of power consumption over the first code segment, which distribution includes finer grained power consumption levels attributed to granular segments of code within the first code segment;
wherein said distribution of power consumption over the first code segment is obtained from the total power consumption for the first code segment;
wherein said distribution of power consumption is obtained by using the program characteristics and power modeling information associated with one or more of: (a) the first code segment; and (b) a subset code of the first code segment;
identifying variations in power consumption during different iterations of execution of a same segment of code; and
linking said variations identified to information about program characteristics of particular segments of code, wherein the program characteristics information includes one or more of: (a) characteristic of input data; (b) data availability in a cache; (c) branch penalties; and (d) other factors associated with code execution.

10. The data processing system of claim 7, wherein the utility further performs the functions of:
identifying program characteristics of one or more of: (a) said first segment of program code; and (b) a subset of said first segment of program code;
obtaining a power model information for one or more of: (a) the first segment of program code; and (b) the subset of said first segment of program code;
identifying finer grained power consumption levels by using the program characteristics and power model information corresponding to granular code segments within the first code segment; and
mapping program characteristics information of the granular code segments to corresponding finer grained power consumption levels, wherein the mapping is performed concurrently with a mapping of the finer grained power consumption levels to the granular segments of the first code segment.

11. The data processing system of claim 7, wherein the utility further performs the function of:
obtaining, from said total power consumption, a distribution of power consumption for executing granular segments of program code from code contained within said first segment of program code by using said program characteristics and a power model;
wherein said first segment of program code represents a first level of code granularity; and
wherein said first level of power consumption is measured during an iteration of execution of said first segment of program code.

12. The data processing system of claim 8, further comprising:
a power sub-system that provides power to one or more devices within the data processing system;
wherein said utility further performs the functions of:
determining power consumption by measuring, via the power measurement device, a level of power consumption by one or more devices that receive power from the power sub-system during execution of one or more segments of program code;
wherein said level of power consumption measures power required by the one or more devices to execute said one or more segments of program code; and
wherein said one or more devices includes a processor executing the one or more segments of program code, and wherein the processor consumes a specific level of power in response to executing one or more segments of program code.

13. A computer program product comprising:
a computer readable medium; and
program code on said computer readable medium that when executed within a data processing device, said program code provides the functionality of:
measuring a first level of power consumption corresponding to execution of a first segment of program code;
identifying information about program characteristics of the first segment of program code;
obtaining power model information for the first segment of program code;
determining total power consumption for execution of said first segment of program code by aggregating levels of measured power consumption corresponding to a plurality of iterations of execution of said first segment of program code; and
deriving from said total power consumption a second level of power consumption corresponding to a granular segment of code contained within said first segment of code by using the program characteristics information and power model information that are mapped to particular code segments.

14. The computer program product of claim 13, further comprising program code for:
measuring the first level of power consumption associated with execution of program code for a particular interval of time; and
mapping said first level of power consumption for said particular interval of time to the first segment of program code.

15. The computer program product of claim 13, further comprising program code for:
providing a distribution of power consumption over the first code segment, which distribution includes finer grained power consumption levels attributed to granular segments of code within the first code segment;
wherein said distribution of power consumption over the first code segment is obtained from the total power consumption for the first code segment;
wherein said distribution of power consumption is obtained by using the program characteristics and power modeling information associated with one or more of: (a) the first code segment; and (b) a subset code of the first code segment;
identifying variations in power consumption during different iterations of execution of a same segment of code; and
linking said variations identified to information about program characteristics of particular segments of code, wherein the program characteristics information includes one or more of: (a) characteristic of input data; (b) data availability in a cache; (c) branch penalties; and (d) other factors associated with code execution.

16. The computer program product of claim 13, further comprising program code for:
identifying program characteristics of one or more of: (a) said first segment of program code; and (b) a subset of said first segment of program code;
obtaining a power model information for one or more of: (a) the first segment of program code; and (b) the subset of said first segment of program code;
identifying finer grained power consumption levels by using the program characteristics and power model information corresponding to granular code segments within the first code segment; and
mapping program characteristics information of the granular code segments to corresponding finer grained power consumption levels, wherein the mapping is performed concurrently with a mapping of the finer grained power consumption levels to the granular segments of the first code segment.

17. The computer program product of claim 13, further comprising program code for:
obtaining, from said total power consumption, a distribution of power consumption for executing granular segments of program code from code contained within said first segment of program code by using said program characteristics and a power model;
wherein said first segment of program code represents a first level of code granularity; and
wherein said first level of power consumption is measured during an iteration of execution of said first segment of program code.

18. The computer program product of claim 13, further comprising code for:
determining power consumption by measuring, via a power measurement device, a level of power consumption by one or more devices that receive power from a power sub-system during execution of one or more segments of program code;
wherein said level of power consumption measures power required by the one or more devices to execute said one or more segments of program code; and
wherein said one or more devices includes a processor executing the one or more segments of program code, and wherein the processor consumes a specific level of power in response to executing one or more segments of program code.
